(19) United States
(12) Patent Application Publication
(10) Pub. No.: US 2013/0049184 A1
(43) Pub. Date: Feb. 28, 2013

(54) ELECTRIC DEVICE AND PRODUCTION METHOD THEREFOR

(71) Applicants: Kenji Kasahara, Niihama-shi (JP); Masaya Shimizu, Niihama-shi (JP); Tomoki Kurata, Niihama-shi (JP)

(72) Inventors: Kenji Kasahara, Niihama-shi (JP); Masaya Shimizu, Niihama-shi (JP); Tomoki Kurata, Niihama-shi (JP)

(73) Assignee: SUMITOMO CHEMICAL COMPANY, LIMITED, Chuo-ku, Tokyo (JP)

(21) Appl. No.: 13/583,044

(22) PCT Filed: Mar. 4, 2011
(86) PCT No.: PCT/JP2011/055138

§ 371 Date: Oct. 31, 2012

(30) Foreign Application Priority Data
Mar. 8, 2010 (JP) 2010-050294

(51) Int. Cl. H01L 23/18; H01L 21/56

(52) U.S. Cl. 257/687; 438/118; 257/E23.181; 257/E23.136; 257/E21.502

(57) ABSTRACT

An electronic device includes a support substrate 12, an electric circuit 14 provided in a sealing region set on the support substrate 12, a sealing member 16 provided on the support substrate 12 to surround the sealing region, a sealing substrate 17 bonded to the support substrate 12 with the sealing member 16 interposed therebetween, and a spacer 23 arranged between the support substrate 12 and the sealing substrate 17. The electric circuit 14 includes an electronic element 24 having an organic layer. The sealing member 16 and the spacer 23 are formed using the same material.

### TECHNICAL FIELD

The present invention relates to an electric device and a production method therefor.

### BACKGROUND ART

Electronic elements such as organic EL (Electro Luminescence) elements, organic photoelectric transducer elements, or organic transistors have an organic layer as one of components. The organic layer is easily degraded when coming into contact with the air. Therefore, in an electric device in which electronic elements having an organic layer are mounted, sealing is performed in order to prevent degradation of the elements.

The sealing is performed, for example, by arranging a sealing member so as to surround electronic elements mounted on a support substrate and by bonding a sealing substrate to the support substrate with the sealing member interposed therebetween.

A member that hardly allows gas to pass through is used as a sealing member. Frit seal using glass as such a sealing member is contemplated as one of sealing methods. Frit is flake-like or powder-like glass (hereinafter also simply referred to as “frit glass powder”) that melts at low temperatures as compared with normal glass. A paste-like frit agent in which frit glass powder is dispersed in a solvent is used for frit seal. In frit seal, first, the frit agent is supplied to a support substrate having electronic elements mounted thereon so as to surround the electronic elements, and then, a sealing substrate is bonded to the support substrate with the frit agent interposed therebetween. Thereafter, the frit agent is irradiated with laser light so that the frit agent is heated and fused. When the irradiation of laser light is stopped, the temperature of the frit agent drops and the frit agent is hardened again. The sealing member is thus formed, and the region surrounded by the support substrate, the sealing substrate, and the sealing member is hermetically sealed.

As the sealing substrate and the support substrate are bonded together with the sealing member interposed therebetween, a gap is formed between the substrates by the thickness of the sealing member. The toughness of the electric device can be a problem because the device has a hollow structure in this manner. For example, the sealing substrate or the support substrate may be distorted due to externally applied stress or its own weight, which may cause a crack in the sealing substrate or the support substrate. In an electric device including a light emitting element that emits light toward the sealing substrate, light interference effects such as Newton's rings may become obvious due to distortion of the sealing substrate. Then, in a conventional technique, a spacer for supporting the sealing substrate is provided between the sealing substrate and the support substrate (see, for example, Patent Literature 1).

### CITATION LIST

### Patent Literature

Patent Literature 1: Japanese Patent Application Laid-Open Publication No. 2008-218004

### SUMMARY OF INVENTION

### Technical Problem

In the conventional technique, the spacer is separately provided in addition to the sealing member. Thus, the number of process steps for forming a device is increased.

It is therefore an object of the present invention to provide an electric device including a sealing member and a spacer that is configured to prevent increase in number of steps required to form the sealing member and the spacer.

### Solution to Problem

An electric device according to the present invention includes a support substrate, an electric circuit provided in a sealing region set on the support substrate, a sealing member provided on the support substrate to surround the sealing region, a sealing substrate bonded to the support substrate with the sealing member interposed therebetween, and a spacer arranged between the support substrate and the sealing substrate. The electric circuit includes an electronic element having an organic layer. The sealing member and the spacer are formed using the same material.

In the electric device, it is preferable that the sealing member and the spacer be arranged spaced apart from each other.

It is preferable that the electric device further include a filling member filled in a region surrounded by the support substrate, the sealing substrate, and the sealing member.

In the electric device, it is preferable that the electronic element be an organic EL element, an organic photoelectric transducer element, or an organic transistor.

In the electric device, it is preferable that the electronic element be an organic EL element. The organic EL element emits light toward the sealing substrate. The spacer is arranged in a remaining region excluding a region in which the organic EL element is provided as viewed from one side in a thickness direction of the support substrate.

A method of producing the electronic device according to the present invention includes the steps of: preparing the support substrate on which the electric circuit is provided; supplying a sealing material serving as the sealing member along an outer periphery of the sealing region and supplying a spacer material serving as the spacer in a region surrounded by the sealing material; bonding the sealing substrate to the support substrate with the sealing material serving as the sealing member interposed therebetween; irradiating the sealing material with an electromagnetic beam so that the sealing material is heated and fused; and forming the sealing member by cooling and hardening the sealing material. The sealing material and the spacer material are the same material.

It is preferable that the method of producing the electric device further include the step of heating the supplied sealing material and the supplied spacer material at a temperature lower than a temperature at which the sealing material and the spacer material are fused, after the step of supplying the sealing material and the spacer material and before the step of bonding the sealing substrate to the support substrate.

In the method of producing the electric device, it is preferable that the sealing material and the spacer material be supplied by a printing method.

In the method of producing the electric device, it is preferable that the sealing material and the spacer material be simultaneously printed.

### Effects of Invention

In the present electric device including the sealing member and the spacer, increase in number of steps required to form the sealing member and the spacer can be prevented.

### BRIEF DESCRIPTION OF DRAWINGS

FIG. 1 is a plan view schematically illustrating a display device 11 in the present embodiment.

FIG. 2 is a cross-sectional view of the display device 11 as viewed from a section line II-II depicted in FIG. 1.

FIG. 3 is an enlarged plan view schematically illustrating part of an image display region 18.

FIG. 4 is an enlarged plan view schematically illustrating part of the image display region 18.

FIG. 5 is an enlarged plan view schematically illustrating part of the image display region 18.

FIG. 6 is an enlarged plan view schematically illustrating part of the image display region 18.

FIG. 7 is a diagram illustrating a section structure of the display device depicted in FIG. 1.

FIG. 8 is a diagram illustrating a section structure of an organic EL element.

FIG. 9 is a plan view of the display device during production.

### DESCRIPTION OF EMBODIMENTS

An electric device according to the present invention includes a support substrate, an electric circuit provided in a sealing region set on the support substrate, a sealing member provided on the support substrate to surround the sealing region, a sealing substrate bonded to the support substrate with the sealing member interposed therebetween, and a spacer arranged between the electric circuit and the sealing substrate. The electric circuit includes an electronic element having an organic layer. The sealing member and the spacer are formed using the same material.

The electric device of the present invention is applicable to a variety of electric devices in which an electric circuit including an electronic element having an organic layer is installed. Examples of the electronic element having an organic layer include an organic EL element, an organic photoelectric transducer element, and an organic transistor. For example, the electric device of the present invention is applicable to a display device in which an organic EL element for use as a light source or a backlight for pixels is installed in an electric circuit, a photoelectric transducer in which an organic photoelectric transducer element for use as a solar cell or an optical sensor is installed in an electric circuit, and an electric device in which an organic transistor used to drive or control the organic EL element, the organic photoelectric transducer element, and any other electronic element is installed in an electric circuit. In the following, the electric device of the present invention will be described taking a display device in which an organic EL element for use as a light source for pixels is installed in an electric circuit, as an example.

Display devices mainly include an active matrix driven type device and a passive matrix driven type device. The present invention is applicable to display devices of both kinds. In the present embodiment, an active matrix driven type display device will be described by way of example.

<Configuration of Display Device>

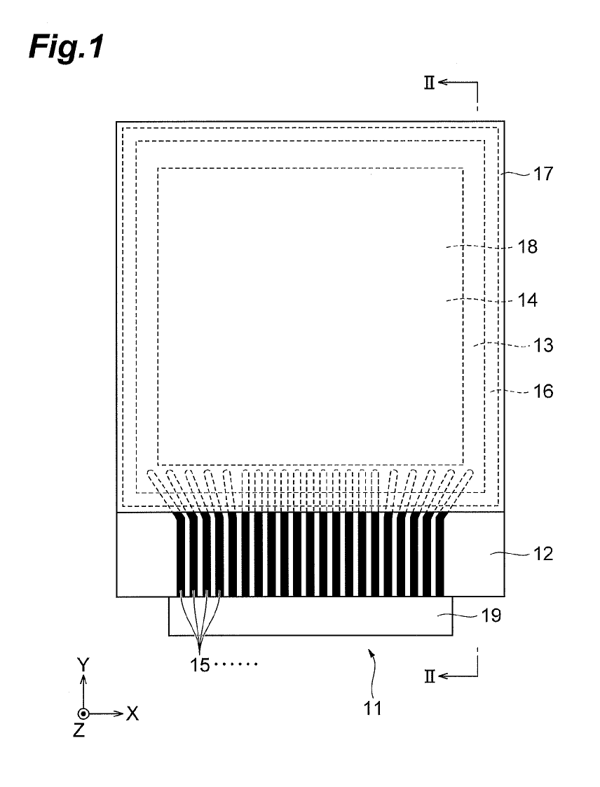

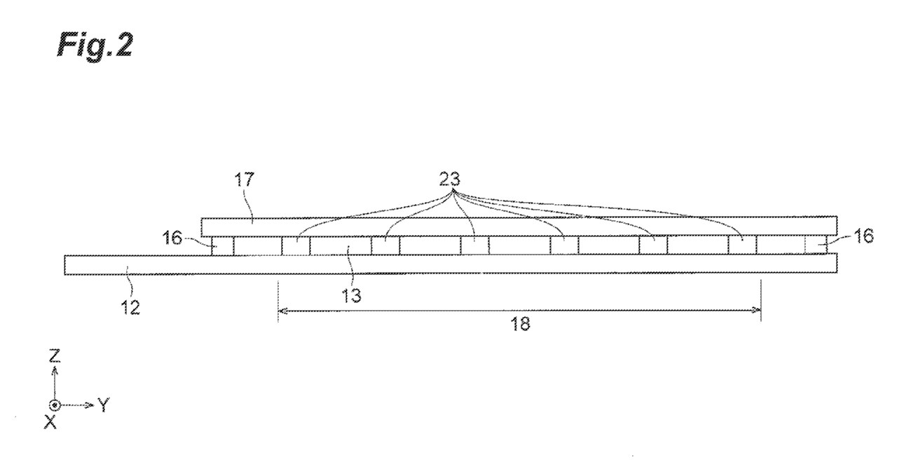

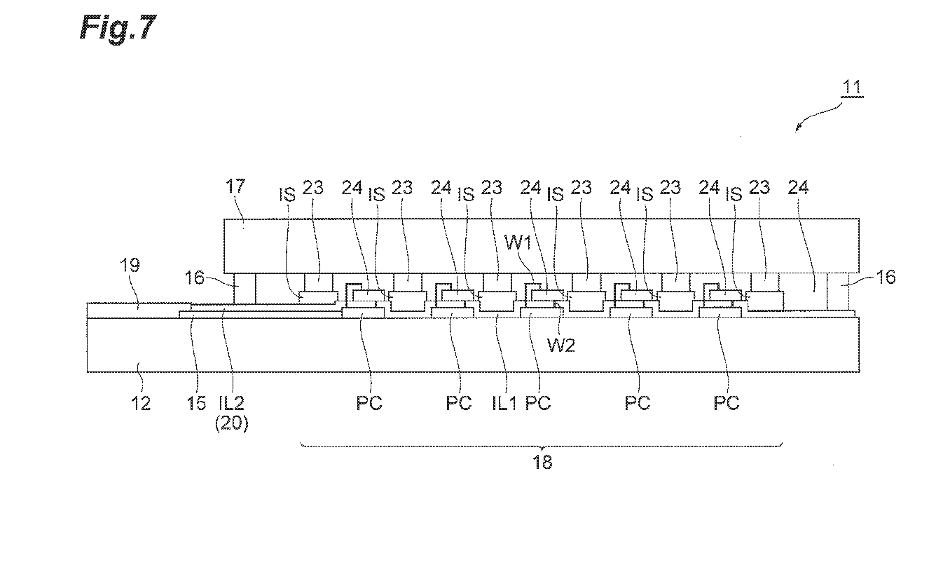

First, a configuration of a display device 11 as an electric device will be described. FIG. 1 is a plan view schematically illustrating the display device 11 in the present embodiment. FIG. 2 is a cross-sectional view of the display device 11 as viewed from a section line II-II depicted in FIG. 1. Similar to FIG. 2, FIG. 7 is a diagram illustrating details of a section structure through EL elements that constitute an electric circuit 14 in the display device depicted in FIG. 1. The display device 11 is an electric device including a support substrate 12, the electric circuit 14 provided in a sealing region 13 set on the support substrate 12, a sealing member 16 provided on the support substrate 12 to surround the sealing region 13, a sealing substrate 17 bonded to the support substrate 12 with the sealing member 16 interposed therebetween, and a spacer 23 arranged between the support substrate 12 and the sealing substrate. The electric circuit 14 includes an electronic element having an organic layer. The sealing member 16 and the spacer 23 are formed using the same material.

In FIG. 1, a portion provided on a surface of the substrate 12 and having a rectangular annular shape corresponds to the sealing member 16, and a portion surrounded with the sealing member 16 corresponds to the sealing region 13.

In the present embodiment, the electric circuit 14 depicted in FIG. 1 is configured to include a number of organic EL elements (electronic elements) 24 for use as light sources for pixels and pixel circuits PC for individually driving the organic EL elements 24, as depicted in FIG. 7. The organic EL element 24 is positioned between isolation walls IS and filled in a space between them. However, for the sake of clarity of description, FIG. 7 depicts that the isolation wall IS and the organic EL element 24 are slightly spaced apart from each other. The pixel circuits PC are formed in a region for displaying image information (hereinafter also referred to as an image display region 18) as viewed from one side in the thickness direction (the Z-axis direction) of the support substrate 12 (hereinafter also referred to as “in a two dimensional view”). The pixel circuit PC is formed of an organic transistor, an inorganic transistor, a capacitor, and other elements. The electronic element 24 may be an organic photoelectric transducer element or an organic transistor in place of an organic EL element.

An insulating film IL1 that covers the pixel circuit PC is formed on the pixel circuit PC. The insulating film IL1 is formed of, for example, an organic insulating film made of resin or an inorganic insulating film. It is preferable to use a heat-resistant film for the insulating film IL1 because part of the insulating film IL1 is heated when a frit agent is heated and fused. Therefore, of the insulating film, at least the insulating film IL1 (or IL2) provided at a place heated when the frit agent is heated and fused is preferably formed of an inorganic insulating film in terms of heat resistance. Examples of such an inorganic insulating film used include metal oxide films such as a silicon oxide film, a silicon nitride film, and a silicon oxynitride film. The thickness of the inorganic insulating film is generally about 50 nm to 3000 nm. The insulating film IL1 (or IL2) can be formed by a known deposition method such as plasma CVD or sputtering in a process of forming the electric circuit.

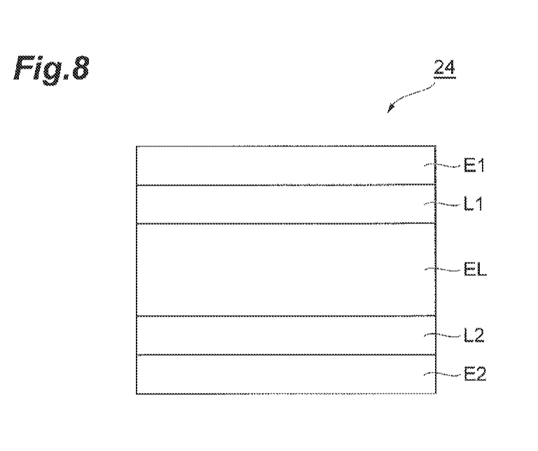

A number of organic EL elements 24 are each provided on the pixel circuit PC. That is, the organic EL elements are each provided on the insulating film IL1 described above in the image display region 18. The organic EL elements 24 are arranged, for example, in a matrix and are arranged at prescribed intervals in a row direction X and a column direction Y in the image display region 18. When the row direction is assumed as the X axis and the column direction is assumed as the Y axis, the thickness direction of the substrate is assumed as the Z axis. These three axes constitute a three-dimensional orthogonal coordinate system. Each organic EL element 24 and the pixel circuit PC are electrically connected with each other through conductors W1 and W2 passing through the insulating film IL1 in the thickness direction. Specifically, the conductor W1 is connected to an upper electrode E1 (see FIG. 8) of the organic EL element 24, and the conductor W2 is connected to a lower electrode E2 (see FIG. 8) of the organic EL element 24. The conductors W1 and W2 are each connected to the pixel circuit PC.

A simple pixel circuit PC is formed of a single transistor. An external electric wiring 15 is connected to the gate of the transistor. Another terminal of the transistor is connected to a power supply potential and the other terminal is connected to the upper electrode E1 (see FIG. 8) of the EL element. The lower electrode E2 (see FIG. 8) of the EL element is connected to the ground potential. When the gate receives input through the electric wiring 15, the transistor turns on, so that voltage is applied between the electrodes E1 and E2 of the organic EL element 24 to cause a light-emitting layer EL (see FIG. 8) therebetween to emit light.

The support substrate 12 is formed of, for example, a glass plate, a metal plate, a resin film, and a stacked structure thereof. The organic EL element 24 provided on the support substrate 12 includes a bottom emission-type organic EL element that emits light toward the support substrate 12 and a top emission-type organic EL element that emits light toward the sealing substrate 17. In a case where the bottom emission-type organic EL elements 24 are mounted on the support substrate 12, a light-transmitting substrate is used as the support substrate 12. In a case where the top emission-type organic EL elements 24 are mounted on the support substrate 12, a non-light transmissive substrate may be used as the support substrate 12.

Many electric wirings 15 for inputting a prescribed electrical signal to the electric circuit 14 are provided in the display device 11. The prescribed electrical signal is an electrical signal for allowing each of a number of organic EL elements 24 to individually emit light at a prescribed light intensity, and means, for example, an electrical signal for individually selecting an element to emit light among the organic EL elements 24 arranged in a matrix, or an electrical signal for designating a light emission intensity of each element. A lot of electric wirings for transmitting electrical signals are required because a number of organic EL elements 24 are provided in the display device 11. The electrical signal is input from an external electrical signal input/output source 19. In the display device 11, the electrical signal input/output source 19 is implemented by a driver. Many electric wirings 15 are provided for the purpose of connecting the electrical signal input/output source 19 with the electric circuit 14 and thus are provided to extend from the inside of the sealing region 13 to the outside of the sealing region 13 on the support substrate 12. Generally, the insulating film IL2 is also provided on many electric wirings 15. In other words, the electric wirings 15 are generally covered with the insulating film IL2. Although FIG. 7 illustrates a case where the insulating films IL1 and IL2 are formed of a common insulating film, they may be formed of different materials. A number of electric wirings 15 may radially extend around the electric circuit 14 from the inside of the sealing region 13 to the outside of the sealing region 13. However, in the present embodiment, as illustrated in FIG. 1, the electric wirings 15 extend from the inside of the sealing region 13 to the outside of the sealing region 13 through one side of the outer periphery of the sealing region 13 so as to converge into the electrical signal input/output source 19. The external electrical signal input/output source 19 is provided outside the sealing region 13 and may be included as a driver in the electric device as in the present embodiment or may not be included in the electric device.

The electric wiring 15 is formed of a metal thin film having high conductivity or a transparent conductive oxide. Specifically, the electric wiring 15 is formed of a thin film of Al, Cu, Cr, W, Mo, ITO, or IZO, or a stacked film thereof. The thickness of the electric wiring 15 is generally about 100 nm to 2000 nm, and the width thereof is generally about 10 μm to 200 μm.

The sealing member 16 is provided on the support substrate 12 so as to surround the sealing region 13 along the outer periphery of the sealing region 13. In other words, the sealing region 13 is a region surrounded by the sealing member 16, and the outer periphery thereof is defined by the sealing member 16. A number of electric wirings 15 are provided to extend from the inside of the sealing region 13 to the outside of the sealing region 13 as described above, so that the sealing member 16 extending along the outer periphery of the sealing region is arranged so as to cross a number of electric wirings 15 in a two-dimensional view. In the present embodiment, a number of electric wirings 15 are covered with the insulating film IL2 as described above, so that the sealing member 16 is provided on the electric wirings 15 with the insulating film IL2 interposed therebetween.

A spacer 23 is further provided on the support substrate 12. The spacer 23 is provided in a region surrounded by the sealing member 16. That is, the spacer 23 is provided in the sealing region 13. The spacer 23 in the present embodiment is not provided so as to be fixed on the support substrate 12 but provided in abutment with the support substrate 12 as described later.

The spacer 23 is provided for the purpose of preventing distortion of the sealing substrate 12. The spacer 23 is provided in such an arrangement in that stress applied to the sealing substrate 17 is distributed so that the stress applied to the sealing substrate 17 can be avoided from concentrating on a particular place. For example, the spacer 23 is formed in a continuous manner in a two-dimensional view and provided in a grid pattern or a stripe pattern. The spacer 23 may be provided dispersively. For example, a plurality of column-like spacers 23 may be dispersively arranged on the support substrate 12, or a plurality of column-like spacers 23 may be dispersively arranged at prescribed intervals in the row direction X and the column direction Y in a matrix.

The sealing member 16 and the spacer 23 may be physically connected. However, it is preferable that the sealing member 16 and the spacer 23 be arranged physically spaced apart from each other. In the case where the sealing member 16 and the spacer 23 are physically connected as described later, when a sealing material serving as the sealing member is heated and fused, the electric circuit is also heated through a spacer material serving as the spacer 23. As a result, the characteristics of the electric circuit may be deteriorated. However, by arranging the sealing member 16 and the spacer 23 spaced apart from each other, the spacer material and the electric circuit 14 are prevented from being heated when the sealing material is heated and fused. As a result, deterioration of the characteristics of the electric circuit 14 can be prevented.

As long as the spacer 23 is provided in such an arrangement in that stress applied to the sealing substrate 17 is distributed, the arrangement of the spacer 23 is not limited in terms of stress. However, in the case where the top emission-type organic EL elements that emit light toward the sealing substrate 17 are provided on the support substrate, light may be blocked by the spacer 23. Therefore, it is preferable that spacer 23 be arranged in a remaining region excluding the regions in which the organic EL elements are provided as viewed from one side in the thickness direction of the support substrate. In the case where the bottom emission-type organic EL elements that emit light toward the support substrate are provided, the spacer 23 may be arranged irrespective of the arrangement of the organic EL elements.

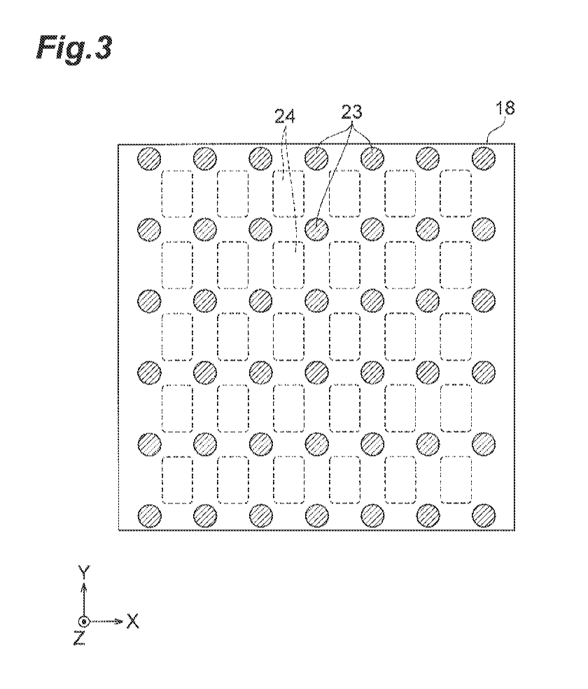

Referring to FIG. 3 to FIG. 6, the arrangement of the spacers 23 in the case where the top emission-type organic EL elements are provided will be described below.

FIG. 3 to FIG. 6 are enlarged plan views schematically illustrating part of the image display region 18. In FIG. 3 to FIG. 6, each organic EL element 24 is depicted by a broken line in an approximately rectangular shape, each spacer 23 is depicted by a solid line, and a portion representing the spacer 23 is hatched.

As previously mentioned, the organic EL elements 24 are arranged at prescribed intervals in the row direction X and the column direction Y in a matrix. In general, the isolation walls IS (see FIG. 7) are provided to separate the organic EL elements 24 from each other on the support substrate 12. The isolation walls IS are provided, for example, in a grid pattern in a two-dimensional view. The organic EL elements are each provided in a region surrounded by this grid-like isolation walls. In other words, in FIG. 3 to FIG. 6, the isolation walls IS are provided in a remaining region excluding the regions in which the organic EL elements 24 are provided. The arrangement of the isolation walls is not limited to the grid pattern. For example, stripe-like isolation walls may be provided. In this case, for example, a plurality of isolation walls extending in the row direction X are provided at prescribed intervals in the column direction Y. The organic EL elements are each provided between the isolation walls and are arranged at prescribed intervals in the row direction X between the isolation walls.

As described above, the spacers 23 are provided in the remaining region excluding the regions in which the organic EL elements 24 are provided in a two-dimensional view. Therefore, for example, in the case where the isolation walls are provided, the spacers 23 are provided on the isolation wall IS in a two-dimensional view. The spacers 23 may be provided in contact with the isolation walls IS. However, in general, each spacer 23 is arranged on the corresponding isolation wall with a conductive thin film or an insulating film interposed therebetween.

In the present embodiment as illustrated in FIG. 3 to FIG. 6, the remaining region excluding the regions in which the organic EL elements 24 are provided is set in a grid pattern. For example, the spacers 23 are provided at all the intersections of the grid as depicted in FIG. 3.

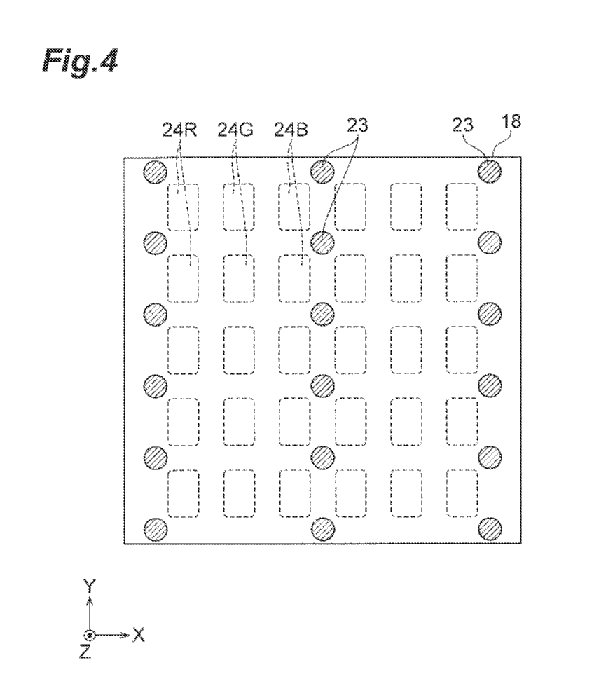

It is not always necessary to provide the spacers 23 at all the intersections of the grid. For example, in a case of a color display device, three kinds of organic EL elements 24R, 24G, and 24B that emit red, green, and blue lights, respectively, are often provided. The spacers 23 may be provided on every prescribed intersections (“every two intersections” in FIG. 4) in the row direction X, in accordance with the number of kinds of elements provided (“three kinds” in FIG. 4).

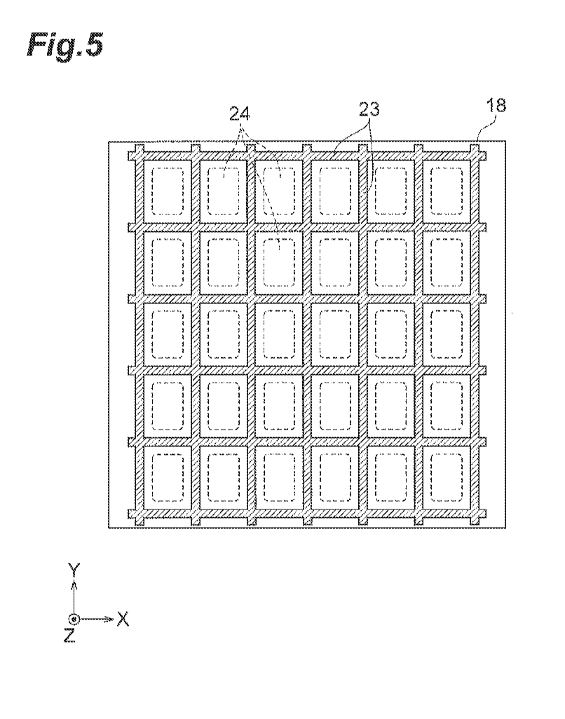

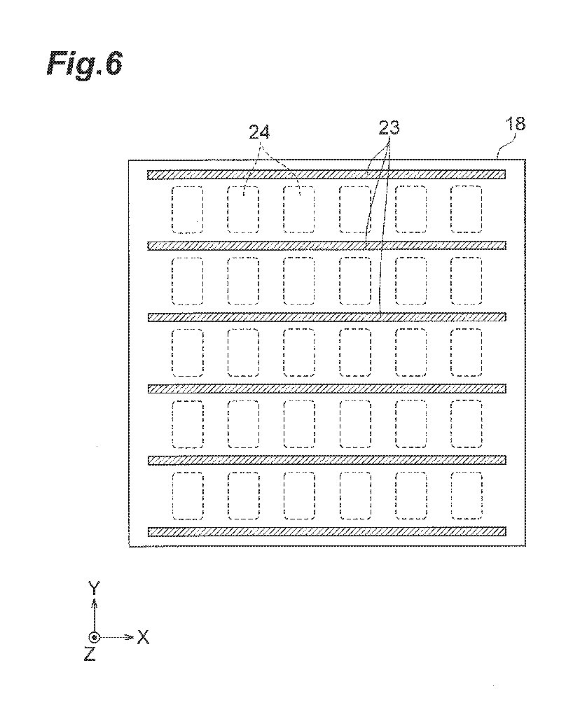

As previously mentioned, the spacer 23 may be formed to be continuous or may be provided in a grid pattern (see FIG. 5) or a stripe pattern (see FIG. 6). FIG. 5 illustrates an example in which a plurality of spacers 23 extending in the row direction X and a plurality of spacers 23 extending in the column direction Y are provided between all the organic EL elements. However, it is not always necessary that the spacers 23 be provided between all the organic EL elements, as is the case with the spacers 23 arranged dispersively as described above. FIG. 6 illustrates an example in which a plurality of spacers 23 extending in the row direction X are provided between all the organic EL elements. However, it is not always necessary that the spacers 23 be provided between all the organic EL elements, as is the case with the spacers 23 arranged dispersively as described above.

The width and thickness of the sealing member 16 are set in consideration of the required hermeticity, the characteristics of the sealing material, and other matters. The width is generally about 500 μm to 2000 μm. The thickness is generally about 5 μm to 50 μm. In the case where the column-like spacer is provided, the width thereof is generally about 10 μm to 80 μm. In the case where the spacer 23 extending in a continuous manner in a prescribed direction in a two-dimensional view is provided, the width thereof is generally about 10 μm to 80 μm. In a case where the spacer 23 is formed by a method described later, the spacer having approximately the same thickness as the sealing member 16 is formed.

The sealing substrate 17 is bonded to the support substrate with the sealing member 16 interposed therebetween. The sealing substrate 17 is formed of a glass plate, a metal plate, a resin film, and a stacked structure thereof. In the case where the top emission-type organic EL elements that emit light toward the sealing substrate 17 are mounted on the support substrate 12, the sealing substrate 17 is formed of a light-transmitting member.

<Method of Producing Display Device>

A method of producing a display device will now be described.

A method of producing the electric device according to the present invention includes the steps of preparing the support substrate on which the electric circuit is provided, supplying a sealing material serving as the sealing member along the outer periphery of the sealing region and supplying a spacer material serving as the spacer in a region surrounded by the sealing material, bonding the sealing substrate to the support substrate with the sealing material serving as the sealing member interposed therebetween, irradiating the sealing material with an electromagnetic beam so that the sealing material is heated and fused, and forming the sealing member by cooling and hardening the sealing material. The sealing material and the spacer material are the same material.

(Step of Preparing Support Substrate on which Electric Circuit is Provided)

First, the support substrate 12 on which the electric circuit 14 is provided as illustrated in FIG. 1 is prepared. In the present embodiment, the electric wirings 15 are also provided on the support substrate 12. Therefore, the support substrate on which the electric circuit 14 and the electric wirings 15 are provided is prepared. More specifically, the support substrate 12 on which the electric circuit 14 having the circuits for driving the organic EL elements and a plurality of organic EL elements 24 and the electric wirings 15 are formed is prepared. The support substrate 12 on which the electric circuit 14 and the electric wirings 15 are provided may be prepared by forming circuits PC for driving the organic EL elements 24 and the electric wirings 15 on the support substrate 12 and by additionally forming a plurality of organic EL elements 24 thereon.

The pixel circuits PC and the electric wirings 15 can be formed using a well-known semiconductor technique.

The organic EL element 24 is configured such that a plurality of layers are stacked. Specifically, as illustrated in FIG. 8, the organic EL element 24 is configured to include a pair of electrodes E1 and E2 and a light-emitting layer EL provided between the electrodes E1 and E2. For example, the upper electrode E1 may be a cathode, and the lower electrode E2 may be an anode, or vice versa. The organic EL element 24 may include, in addition to the light-emitting layer EL, an anode-side organic layer L2 including a hole injection layer, a hole transport layer, an electron block layer, etc., and a cathode-side organic layer L1 including an electron injection layer, an electron transport layer, a hole block layer, etc., if necessary. The electrode E1 or E2 may be in direct contact with the light-emitting layer EL. The organic EL element 24 can be formed on the pixel circuit PC (see FIG. 7) by successively stacking the plurality of layers that constitute the organic EL element 24. The layers can be successively stacked by a dry method such as a vapor deposition method and a sputtering method, or a wet method such as an inkjet method, a nozzle printing method, and a spin-coating method.

(Step of Supplying Materials Serving as Sealing Member and Spacer)

In this step, a sealing material serving as the sealing member 16 is supplied along the outer periphery of the sealing region 13, and a spacer material serving as the spacer 23 is supplied in the region surrounded by the sealing material. The sealing material and the spacer material may be supplied to at least one of the support substrate 12 and the sealing substrate 17. In the present embodiment, the sealing material and the spacer material are supplied onto the sealing substrate 17.

The same material is used as the sealing material and the spacer material. A paste-like frit agent is used in the present embodiment as the sealing material and the spacer material in this manner. The paste-like frit agent is composed of frit glass powder and a vehicle. The vehicle is made of a binder and a solvent for dispersing the binder and the frit glass powder. A low melting-point glass powder that contains V₂O₅, VO, SnO, SnO₂, P₂O₅, Bi₂O₃, B₂O₃, ZnO, SiO₂, or other materials can be used as the frit glass powder. For example, BAS115, BNL 115BB-N, FP-74, and the like manufactured by ASAHI GLASS CO., LTD. can be used. Nitrocellulose, methyl acrylate, ethyl acrylate, butyl acrylate, ethyl cellulose, hydroxypropyl cellulose, butyl cellulose, or the like can be used as the binder. Butyl carbitol acetate, propylene glycol diacetate, methyl ethyl ketone, ethyl carbitol acetate, amyl acetate, and the like can be used as the solvent.

The sealing material and the spacer material can be supplied by a known coating method. For example, the sealing material and the spacer material can be supplied by a printing method such as a screen printing method, an offset printing method, an inkjet printing method, and a nozzle printing method, and a coating method using a dispenser. Among those, the printing method is preferred because the film thickness controllability such as uniformity of the film thickness of the sealing material on the coated surface and reproducibility of a coating state is excellent, and because the time required for coating is short. The screen printing method is more preferred

In supply of the sealing material and the spacer material, the sealing material and the spacer material may be supplied in different steps. However, in order to reduce the number of steps, it is preferable to supply the sealing material and the spacer material simultaneously in the same step. Examples of the method of simultaneously supplying the sealing material and the spacer material may include the printing method as described above.

As previously mentioned, the sealing member and the spacer are preferably arranged spaced apart from each other. Therefore, it is preferable that the sealing material and the spacer material be supplied to be spaced apart from each other so that they are not connected.

Next, in the present embodiment, preliminary baking is performed. More specifically, after the sealing material and the spacer material are supplied and before the step of bonding the sealing substrate 17 to the support substrate 12, the supplied sealing material and the supplied spacer material are heated at a temperature lower than the temperature at which the sealing material and the spacer material are fused. An unnecessary component in the sealing material and the spacer material is removed by performing the preliminary baking. Specifically, the solvent is vaporized and the binder is burnt by performing the preliminary baking, whereby the vehicle is removed from the frit agent. As a result, the frit glass powder is left on the sealing substrate 17. Furthermore, the sealing material and the spacer material can be fixed to the sealing substrate by performing the preliminary baking. In addition, it can be prevented that an unnecessary gas is vaporized from the sealing material and the spacer material during the step of heating and fusing the sealing material and after the sealing, because the unnecessary component is removed in advance by the preliminary baking. Thus, the gas that may cause degradation of the electronic elements can be prevented from being discharged from the sealing material and the spacer material into the sealing region. The preliminary baking is performed at a temperature lower than the temperature at which the sealing material and the spacer material are fused, and at a temperature that can remove the vehicle. For example, the preliminary baking is performed, for example, at 300° C. to 500° C. In a case where a member that is chemically changed when heated is provided on the sealing substrate 17 in addition to the sealing material and the spacer material, it is preferable to perform the preliminary baking at such a temperature that does not cause the other member to be chemically changed.

(Step of Bonding Sealing Substrate to Support Substrate)

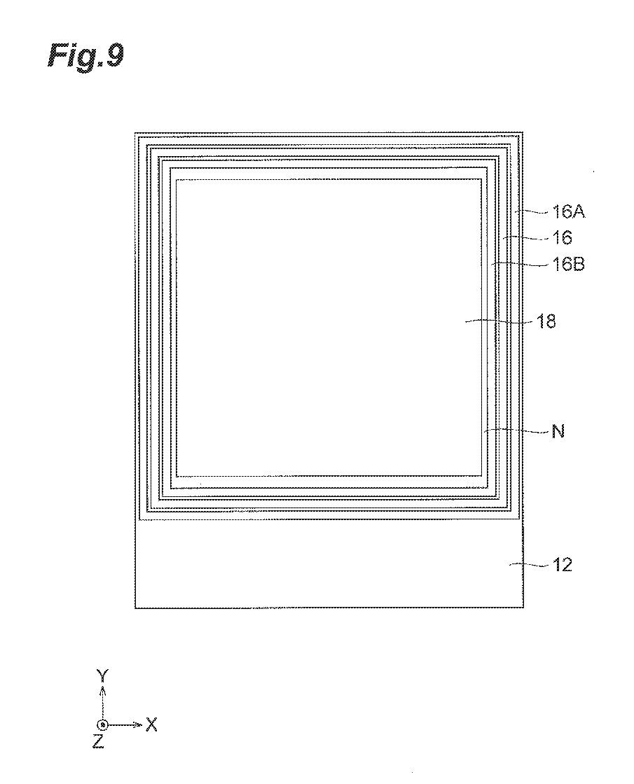

Next, the sealing substrate is bonded to the support substrate. In the present embodiment, preliminary sealing is performed. In the preliminary sealing, for example, first, a preliminary sealing material serving as a preliminary sealing member is supplied along the sealing material outside the sealing material. Then, the sealing substrate 17 is bonded to the support substrate 12 in a vacuum or in an inert gas atmosphere. FIG. 9 is a plan view of the display device after bonding the substrates, in which depiction of the sealing substrate 17 is omitted. A preliminary sealing member 16A is positioned so as to surround the outside of the sealing member 16. In this figure, a dam member 16B to be used when a filling material N is filled in the sealed space is also depicted. The dam member 16B will be described later.

For example, a light-curable resin is used as the preliminary sealing material. After supplying the preliminary sealing material, preliminary sealing is performed by irradiating the preliminary sealing material with light to cure the preliminary sealing material. For example, ultraviolet-curable epoxy resin, ultraviolet-curable acrylic resin, or other materials can be used as the preliminary sealing material. Although the preliminary sealing member is not depicted in FIG. 1, in actuality, for example in FIG. 1, two lines corresponding to the sealing member and the light-curable resin extend along the outer periphery of the sealing region similar to the illustration in FIG. 9, because the light-curable resin extends along the sealing member 16 in the case where the preliminary sealing is performed. In a case where the light-curable resin and the sealing member 16 are arranged in proximity to each other, it is preferable that the light-curable resin and the sealing member 16 be arranged at least 0.5 mm apart from each other because the light-curable resin may be burnt when the sealing material is heated and fused by a laser.

In another embodiment, a part that is necessary for preliminary sealing but unnecessary for the configuration of the electric device may be detached from the electric device after the frit sealing. For example, the substrate may be divided between the light-curable resin used in the preliminary sealing and the sealing member, and the part where the light-curable resin is arranged may be detached as an unnecessary part from the electric device. In this case, during preliminary sealing, the light-curable resin may be arranged apart from the sealing member 16 by a prescribed distance so as to surround the sealing member 16.

In the case where preliminary sealing is performed in a vacuum, the degree of vacuum is preferably 1 Pa to 90 kPa. In the case where preliminary sealing is performed in an inert gas atmosphere, the preliminary sealing is preferably performed in an inert gas atmosphere with a dew point of −70° C. or lower. Argon or nitrogen can be used as an inert gas. Ultraviolet rays can be used as light emitted to the preliminary sealing material. By performing the preliminary sealing in a vacuum or in an inert gas atmosphere, the moisture concentration and the oxygen concentration in the sealing region can be reduced to be lower than those of the atmosphere. Although the hermeticity is low in the preliminary sealing, frit sealing as described later is performed in the preliminarily sealed state to enhance the hermeticity, whereby the moisture concentration and the oxygen concentration in the sealing region can be kept lower than those of the atmosphere.

The bonding between the sealing substrate 17 and the support substrate 12 may be performed using an alignment mark as a reference. For example, the sealing substrate and the support substrate may be given respective alignment marks in advance, and the positions of the alignment marks may be recognized using an optical sensor. Then, alignment of the sealing substrate and the support substrate is performed based on the recognized positional information. Thereafter, the sealing substrate and the support substrate may be bonded together.

(Step of Heating and Fusing Sealing Material)

In the present embodiment, after the preliminary sealing, the sealing material is heated and fused in the atmosphere. In this step, the spacer material is not heated. The heating and fusing of the sealing material is performed by irradiating the sealing material serving as the sealing member 16 with an electromagnetic beam.

In the present embodiment, the irradiation of an electromagnetic beam is performed from the sealing substrate 17 side, of the support substrate 12 and the sealing substrate 17. Specifically, a head for emitting an electromagnetic beam (hereinafter also referred to as an electromagnetic beam irradiation head) is arranged above the sealing substrate 17 to irradiate the sealing substrate 17 with an electromagnetic beam. The electromagnetic beam emitted from the electromagnetic beam irradiation head passes through the sealing substrate 17 and the sealing material serving as the sealing member 16 is irradiated with the electromagnetic beam. Light having a high energy density is suitably used as the electromagnetic beam. Laser light is suitably used.

It is preferable to use light having a wavelength at which the sealing material efficiently absorbs light energy and which passes through the sealing substrate 17 with a high transmittance. In other words, a member through which an electromagnetic beam passes is suitably used as the sealing substrate 17, and a material that absorbs an electromagnetic beam is suitably used as the sealing material. The peak wavelength of light to be used as an electromagnetic beam is generally 190 nm to 1200 nm, and preferably 300 nm to 1100 nm. Examples of a laser device that emits an electromagnetic beam may include a YAG laser, a semiconductor laser (diode laser), an argon ion laser, and an excimer laser.

The irradiation of an electromagnetic beam can be performed, for example, using a control device capable of three-dimensionally moving the electromagnetic beam irradiation head. For example, the electromagnetic beam irradiation head may be arranged at a prescribed distance from the sealing material, and the electromagnetic beam irradiation head may be scanned along the sealing material while irradiating the sealing material with an electromagnetic beam. Although the irradiation of an electromagnetic beam may be performed with the light intensity of the electromagnetic beam being varied, it is preferable that throughout the entire region in which the sealing material is arranged be irradiated with the electromagnetic beam at the same light intensity. This is because the setting of the device is easy. When the light intensity is varied, the scanning speed of the electromagnetic beam irradiation head may be reduced at that time. However, in the case of scanning the electromagnetic beam irradiation head with a light intensity being kept constant, the time required for the electromagnetic beam irradiation head to make a round along the sealing material can be shortened. As long as the electromagnetic beam irradiation head is scanned relative to the sealing substrate and the support substrate bonded together, the irradiation of an electromagnetic beam is not only performed by moving the electromagnetic beam irradiation head but by moving the sealing substrate 17 and the support substrate 12 bonded together or may be performed by moving both the sealing substrate 17 and the support substrate 12 bonded together as well as the electromagnetic beam irradiation head. The movement of sealing substrate 17 and the support substrate 12 bonded together can be carried out by placing the sealing substrate 17 and the support substrate 12 bonded together on a stage having a moving mechanism and by moving this stage.

It is preferable to adjust the spot diameter of the electromagnetic beam. The size of the spot diameter can be adjusted by using an optical element such as a condenser lens. Preferably, the size of the spot diameter at the sealing material is generally adjusted approximately to the width of the sealing material. This is because if the spot diameter is too small, the sealing material is locally heated, whereas if the spot diameter is too large, a member other than the sealing material is also heated. In the present description, the spot diameter means a diameter of a curve obtained by connecting positions where the light intensity is “1/ê2” with respect to the light intensity on the optical axis when the electromagnetic wave is cut along a plane perpendicular to the optical axis, where the symbol “e” represents Napier's constant. Although the curve is not always a perfect circle, the diameter of the curve can be obtained by approximating the curve to a circle and calculating the diameter of the circle.

In this manner, only the sealing material can be heated and fused by adjusting the spot diameter of the electromagnetic beam. Supposing that the spacer material is also heated and fused, the electric circuit is also heated because of the spacer material being heated, so that the electric circuit may be degraded by heat. However, in the present embodiment, the spacer material is not heated and fused, thereby preventing the electric circuit from being degraded in this step. In the case where the sealing material and the spacer material are arranged spaced apart from each other, even when the sealing material is heated, the heat is not transferred to the spacer material. Therefore, the electric circuit can be prevented from being heated, and the electric circuit can thus be prevented from being degraded in this step.

(Step of Forming Sealing Member)

Next, the sealing member 16 is formed by cooling and hardening the fused sealing material. The fused sealing material may be cooled by decreasing the temperature surrounding the display device, or the temperature may be decreased by natural cooling. For example, the temperature of the sealing material is decreased naturally by stopping irradiation of the electromagnetic beam, so that the fused sealing material hardens naturally. The spacer material in the present embodiment, though not fused, is solidified by the preliminary baking and therefore functions suitably as the spacer 23. The spacer 23 is fixed to the sealing substrate 17 by the preliminary baking but only abuts on the support substrate side because no process for fixing it to the support substrate is performed.

The sealing member 16 and the spacer 23 of almost the same thickness as each other are formed by forming the sealing member 16 and the spacer 23 in this manner. The distance between the support substrate 12 and the sealing substrate 17 may differ between the place where the sealing member 16 is provided and the place where the spacer 23 is provided. This is because the electric circuit (in this embodiment, the organic EL element) may be provided in the place where the spacer 23 is provided, and, thus, the thickness may be increased accordingly. However, the thickness of the organic EL element 24 is so small that can be ignored when compared with the thickness of the sealing member 16 and the spacer 23. Therefore, even when the distance between the support substrate and the sealing substrate may differ between the place where the sealing member is provided and the place where the spacer is provided, the stress resulting from this difference is small and its effect on the sealing substrate is little. In a case where the thickness of the electric circuit 14 is large and the resulting stress is large, the thickness of the support substrate 12 or the sealing substrate 17 can be adjusted so that the resulting stress is reduced. For example, a ridge may be formed in the support substrate 12 or the sealing substrate 17 along the place where the sealing member 16 is provided. Conversely, a groove may be formed in the support substrate 12 or the sealing substrate 17 at the place where the electric circuit is provided.

As described above, the sealing member 16 and the spacer 23 are formed using the same material, whereby the spacer 23 can be formed simultaneously in the step of forming the sealing member 16. Therefore, it is not necessary to separately provide a step for forming the spacer 23 even in the device including the spacer 23 in addition to the sealing member, thereby preventing increase of the number of steps required to produce the device.

In another embodiment in the present embodiment, the light emitting device may additionally have a filling member N (see FIG. 9) to be filled in a region surrounded by the support substrate 12, the sealing substrate 17, and the sealing member 16.

As described above, for example, in the case where the top emission-type organic EL elements are provided, light emitted from the organic EL element 24 passes through a space between the organic EL element 24 and the sealing substrate 17 and further through the sealing substrate 17 to be output to the outside. When the space between the organic EL element 24 and the sealing substrate 17 is not filled with the filling member N (see FIG. 9), the refractive index thereof is about “1.” Then, when a glass substrate is used as the sealing substrate 17, the refractive index thereof is about 1.45 to 1.55, so that there is a difference in refractive index between the space described above and the sealing substrate 17. This refractive index difference causes reflection. In the present embodiment, the space is filled with the filling member N to reduce the refractive index difference between the space and the sealing substrate 17, thereby preventing reflection caused by the refractive index difference between the space and the sealing substrate 17.

When the refractive index of the sealing substrate 17 is n1 and the refractive index of the filling member N is n2, it is preferable that n1 and n2 satisfy the following relationship.

|n1−n2|<n1−1

In the formula above, the left side represents the absolute value of the refractive index difference between the support substrate 17 and the filling member N, and the right side represents the refractive index difference between the support substrate 17 and the air. The provision of the filling member N in this manner prevents light emitted from the organic EL element from being reflected inside the device and prevents light from being confined inside the device.

For example, a light-curable resin is used for the filling member N. In a case where a material having a high flowability is used as the light-curable resin before curing, the dam member 16B (see FIG. 9) may be used in order to retain the material in a prescribed position. The dam member 16B is formed, for example, so as to surround the image display region 18 along the sealing member 16 in the inside of the sealing member 16. The filling member N is filled in a region surrounded by the dam member 16B. A material having a form-holding ability higher than the material serving as the filling member N is used as the material serving as the dam member 16B. The spacer 23 is also provided in the region surrounded by the dam member 16B.

The dam member 16B and the filling member N are provided on the sealing substrate 17, for example, after the sealing material and the spacer material are preliminarily baked and before the support substrate 12 and the sealing substrate 17 are bonded together.

It is preferable that the dam member 16B be formed using an ultraviolet-curable or thermosetting material in terms of sealing performance. For example, the dam member 16B is formed of epoxy resin or acrylic resin. It is preferable that the filling member N be formed of a light-transmitting material for light having wavelengths of emission light from the organic EL element 24. For example, the filling member N is formed of epoxy resin, acrylic resin, methacrylic resin, fluoren-based resin, cycloolefin polymer.

In the case where the dam member 16B is formed in addition to the filling member N, a material serving as the dam member 16B is arranged first. First, a material serving as the dam member 16B is supplied along the arrangement of the sealing material in the inside of the sealing material on the sealing substrate 17. Then, a material serving as the filling member N is supplied in a region surrounded by the material serving as the dam member 16B. Thereafter, as described above, the sealing substrate 17 is bonded to the support substrate 12. For the dam member 16B, it is preferable to use the same material as the preliminary sealing material 16A arranged along the sealing member 16 outside the sealing member 16 in the preliminary sealing as described above. It is further preferable to supply the material serving as the dam member 16B and the preliminary sealing material simultaneously in the same step. The number of steps can be reduced by forming the preliminary sealing material and the dam member 16B in the same step in this manner. The material serving as the dam member 16B and the filling member N can be supplied by a method similar to the foregoing methods described as a method of supplying the sealing material and the spacer material.

After the sealing substrate 17 is bonded to the support substrate 12, the dam member 16B and the filling member N are cured, for example, by irradiation of light.

The display device in such a manner that the electric circuit 14 is provided on the support substrate has been described above. An electric circuit may be provided also on the sealing substrate 17. For example, pixel circuits PC for driving part of the electric circuit 14 may be provided on the support substrate while the organic EL elements 24 may be provided on the sealing substrate 17. The pixel circuit PC (see FIG. 7) provided on the support substrate 12 and the organic EL element 24 provided on the sealing substrate 17 are electrically connected with each other through a prescribed conductive member.

In the foregoing display device, the display device in which the organic EL element 24 is provided as an electronic element having an organic layer has been described. However, an organic transistor as the electronic element having an organic layer may be used as the transistor that constitutes part of the pixel circuit PC.

### REFERENCE SIGNS LIST

11 display device
12 support substrate
13 sealing region
14 electric circuit
15 electric wiring
16 sealing member
17 sealing substrate
18 image display region
19 electrical signal input/output source
23 spacer
24 organic EL element

1. An electric device comprising:
a support substrate;
an electric circuit provided in a sealing region set on the support substrate;
a sealing member provided on the support substrate to surround the sealing region;
a sealing substrate bonded to the support substrate with the sealing member interposed therebetween; and
a spacer arranged between the support substrate and the sealing substrate, wherein
the electric circuit includes an electronic element having an organic layer, and
the sealing member and the spacer are formed using a same material.

2. The electric device according to claim 1, wherein the sealing member and the spacer are arranged spaced apart from each other.

3. The electric device according to claim 1, further comprising a filling member filled in a region surrounded by the support substrate, the sealing substrate, and the sealing member.

4. The electric device according to claim 1, wherein the electronic element is an organic EL element, an organic photoelectric transducer element, or an organic transistor.

5. The electric device according to claim 1, wherein
the electronic element is an organic EL element,
the organic EL element emits light toward the sealing substrate, and
the spacer is arranged in a remaining region excluding a region in which the organic EL element is provided as viewed from one side in a thickness direction of the support substrate.

6. A method of producing the electronic device according to claim 1, the method comprising the steps of:
preparing the support substrate on which the electric circuit is provided;
supplying a sealing material serving as the sealing member along an outer periphery of the sealing region and supplying a spacer material serving as the spacer in a region surrounded by the sealing material;
bonding the sealing substrate to the support substrate with the sealing material serving as the sealing member interposed therebetween;
irradiating the sealing material with an electromagnetic beam so that the sealing material is heated and fused; and
forming the sealing member by cooling and hardening the sealing material, wherein
the sealing material and the spacer material are the same material.

7. The method of producing the electronic device according to claim 6, further comprising the step of heating the supplied sealing material and the supplied spacer material at a temperature lower than a temperature at which the sealing material and the spacer material are fused, after the step of supplying the sealing material and the spacer material and before the step of bonding the sealing substrate to the support substrate.

8. The method of producing the electronic device according to claim 6, wherein the sealing material and the spacer material are supplied by a printing method.

9. The method of producing the electronic device according to claim 8, wherein the sealing material and the spacer material are simultaneously printed.
